(19) United States
(12) Patent Application Publication
(10) Pub. No.: US 2012/0238040 A1
(43) Pub. Date: Sep. 20, 2012

(54) PLASMA ETCHING APPARATUS AND PLASMA ETCHING METHOD

(75) Inventors: Kazuhiro KUBOTA, Kurokawa-gun (JP); Yusuke SAITO, Kurokawa-gun (JP); Masanobu HONDA, Kurokawa-gun (JP)

(73) Assignee: TOKYO ELECTRON LIMITED, Tokyo (JP)

(21) Appl. No.: 13/422,360

(22) Filed: Mar. 16, 2012

Related U.S. Application Data
(60) Provisional application No. 61/472,661, filed on Apr. 7, 2011.

(30) Foreign Application Priority Data
Mar. 16, 2011 (JP) 2011-058602

(51) Int. Cl. H01L 21/66; H01L 21/3065

(52) U.S. Cl. 438/5; 156/345.27; 257/E21.529

(57) ABSTRACT

Disclosed is a technology that can obtain high in-plane uniformity of etching while etching a substrate using plasma. A proper temperature of a focus ring capable of performing etching having high in-plane uniformity is identified in advance for each of the multilayers formed on a wafer, the temperature is reflected to a processing recipe as a set temperature, and a heating mechanism and a cooling mechanism are controlled such that the temperature of the focus ring is within an appropriate temperature range including the set temperature thereof for each of the layers to be successively etched. Heat of the focus ring is radiated using a laser and is discharged to a supporting table without using a heater, to independently separate the heating mechanism and the cooling mechanism from each other.

### CROSS-REFERENCE TO RELATED APPLICATIONS

This application is based on and claims priority from Japanese Patent Application No. 2011-058602, filed on Mar. 16, 2011, with the Japanese Patent Office, the disclosure of which is incorporated herein in its entirety by reference. Also, this application claims the benefit of U.S. Provisional Application No. 61/472,661 filed on Apr. 7, 2011, with the United States Patent and Trademark Office, the disclosure of which is incorporated herein in its entirety by reference.

### TECHNICAL FIELD

The present disclosure relates to a technology that performs an etching process onto a substrate using plasma

### BACKGROUND

A parallel flat type plasma etching apparatus used in a process of manufacture of a semiconductor device is configured such that a placing table on which a substrate as a semiconductor wafer is placed constituting a lower electrode, a gas shower head disposed to oppose the placing table constituting an upper electrode, and a ring member, which is referred to as a focus ring, surrounding the substrate on the placing table are installed in a vacuum container. As the semiconductor device requires a fine pattern, a processing with high uniformity is required between substrates or in a plane of the substrate, and in order to meet the demand, for example, the processing parameters, and hardware configuration of the apparatus have been considered and improved. For example, Japanese Patent Application Laid-Open No. 2008-159931 discloses a technique where the temperature of the focus ring is changed and adjusted immediately after starting and during the continuous operation thereafter in order to improve in-plane uniformity of a wafer during an etching process since the temperature of a processing container is different immediately after starting an etching apparatus and during a continuous operation thereafter.

### SUMMARY

A plasma etching apparatus for performing etching with plasma onto a substrate disposed on a placing part in a processing container, the apparatus including: a ring member installed to surround the substrate on the placing part and configured to adjust a plasma state; a heating mechanism configured to heat the ring member; a cooling mechanism configured to cool the ring member; a temperature detector configured to detect a temperature of the ring member; a recipe memory storing a processing recipe including a set temperature of the ring member and having processing conditions for etching the substrate recorded therein; and an executing part reading out the processing recipe from the recipe memory and outputting a control signal for controlling the heating mechanism and the cooling mechanism based on the read-out set temperature of the ring member and a detected temperature of the temperature detector.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal sectional side view illustrating a plasma etching apparatus according to an exemplary embodiment of the present disclosure.

FIG. 2 is a block diagram illustrating the control of a temperature of a focus ring according to the exemplary embodiment.

FIG. 3 is a longitudinal sectional side view illustrating a cooling mode in the temperature control.

FIG. 4 is a longitudinal sectional side view illustrating a heating mode in the temperature control.

FIG. 5 is a longitudinal sectional view illustrating multilayers formed on a wafer according to the exemplary embodiment.

FIG. 6 is a table illustrating an example of a processing recipe according to the exemplary embodiment.

FIG. 7 is a table in which operation conditions of a heating mechanism and a heating mechanism are compiled according to the exemplary embodiment.

FIG. 8 is a flowchart illustrating steps of executing the processing recipe by a program.

FIG. 9 is a graph illustrating an example of temporal variation in a temperature of a focus ring in the temperature control.

FIG. 10 is a longitudinal sectional view illustrating the multilayers after an etching processing.

FIG. 11 is a temperature variation diagram schematically illustrating a relationship between an execution timing of steps of the processing recipe and the temperature of the focus ring.

FIG. 12 is a scatter diagram illustrating the result of Example of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Considering the complicated nature of semiconductor devices, the multilayers on a substrate may be etched in the same vacuum container, and in this case, processing parameters such as a type of gas, and pressure are set according to each layer. While it is required to further improve the uniformity of an etching process, for example, it is also required to achieve high in-plane uniformity even when the multilayers are removed at a moment.

U.S. Pat. No. 6,767,844 discloses a focus ring in which a temperature may be adjusted by bringing the focus ring into contact with a heat conduction means. U.S. Pat. No. 6,795,292 discloses an apparatus provided in a semiconductor processing container having a heater inside a waste ring in contact with a focus ring. However, more studies are needed to improve the high in-plane uniformity.

The present disclosure has been made in an effort to provide a technology that obtains a high in-plane uniformity while plasma etching of a substrate.

An exemplary embodiment of the present disclosure provides an etching apparatus for performing a plasma etching process onto a substrate disposed on a placing part in a processing container. The etching apparatus includes a ring member installed to surround the substrate on the placing part and configured to adjust a plasma state; a heating mechanism configured to heat the ring member; a cooling mechanism configured to cool the ring member; a temperature detector configured to detect a temperature of the ring member; a recipe memory storing a processing recipe including a set temperature of the ring member and having processing conditions for etching the substrate recorded therein; and an executing part reading out the processing recipe from the recipe memory and outputting a control signal for controlling the heating mechanism and the cooling mechanism based on the read-out set temperature of the ring member and a detected temperature of the temperature detector.

In the plasma etching apparatus of the present disclosure, the processing recipe includes a plurality of steps as processing units and the set temperature of the ring member is set for each step.

Further, the plural kinds of layers to be successively etched in the processing container are laminated on the substrate and the plurality of steps included in the processing recipe correspond to steps of etching the plural kinds of layers, respectively.

Still Further, the ring member is electrostatically adsorbed onto an electrostatic chuck disposed on the surface of a supporting part that surrounds the placing part and is cooled by a refrigerant. The plasma etching apparatus of the present disclosure further comprises a gas supply mechanism for heat conduction to supply gas for heat conduction between the ring member and the electrostatic chuck so as to cool the ring member by discharging heat of the ring member to the supporting part side, and the gas supply mechanism constitutes a part of the cooling mechanism and is controlled by the control signal.

In the plasma etching apparatus of the present disclosure, the heating mechanism includes an insulator installed at a lower part of the ring member and a light source part installed outside the processing container and configured to irradiate light for heating to the ring member through the insulator.

Another exemplary embodiment of the present disclosure provides a plasma etching method for performing etching with plasma onto a substrate disposed on a placing part in a processing container, the method including: reading out a processing recipe corresponding to the substrate to be etched, which includes a set temperature of a ring member and has processing conditions for etching the substrate recorded therein, by using the ring member installed to surround the substrate on the placing part and configured to adjust a plasma state, a heating mechanism configured to heat the ring member, and a cooling mechanism configured to cool the ring member; detecting a temperature of the ring member; and controlling the heating mechanism and the cooling mechanism based on the set temperature of the ring member recorded in the read processing recipe and a detected temperature of the temperature detector.

In the plasma etching method of the present disclosure, the plural kinds of layers to be successively etched in the processing container are laminated on the substrate, the processing recipe includes a plurality of steps as processing units to etch each of the plural kinds of layers, and the set temperature of the ring member is set for each step.

According to the exemplary embodiments of the present disclosure, a set temperature of a ring member is recorded in a processing recipe having processing conditions for etching a substrate recorded therein, the temperature of the ring member is detected by a temperature detector, and the heating mechanism and the cooling mechanism are controlled based on the set temperature of the ring member and the detected temperature. As a result, it is possible to obtain a high in-plane uniformity during an etching process.

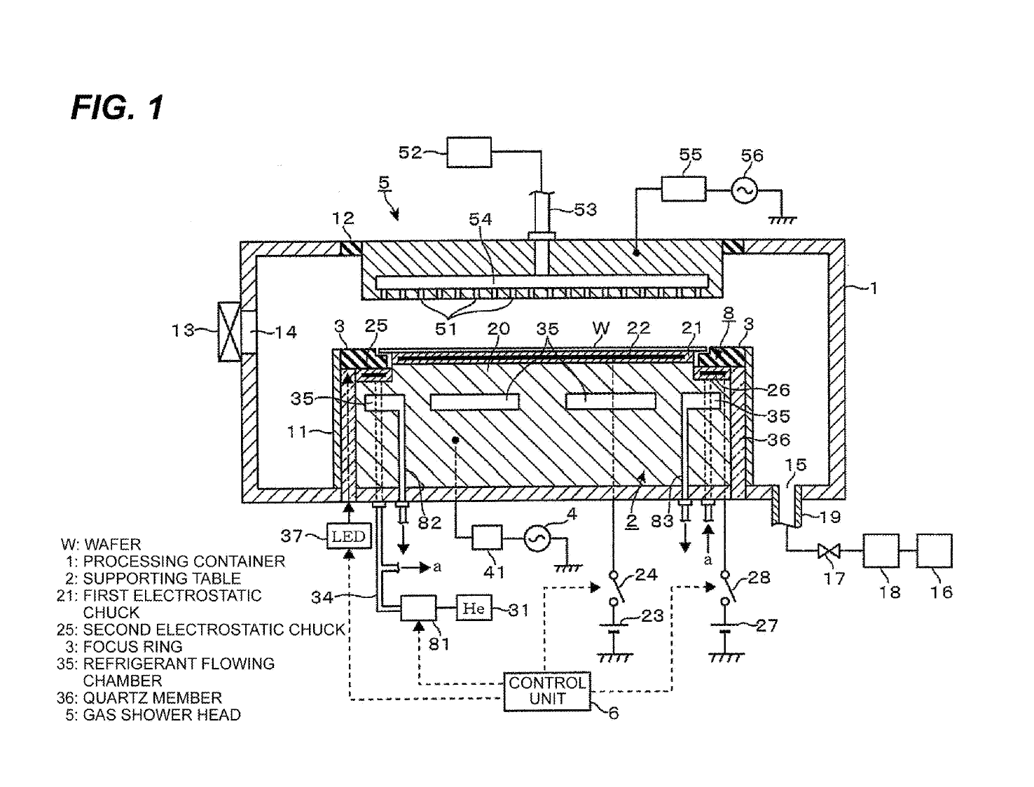

Hereinafter, FIG. 1 illustrates a plasma etching apparatus according to an exemplary embodiment of the present disclosure and reference numeral 1 denotes an airtight processing container (vacuum container) made of, for example, aluminum. A supporting table 2 is installed at a central portion of the bottom of processing container 1. Supporting table 2 is configured in a shape that a circumferential edge of a cylindrical top surface is notched over the entire circumference and a stepped part 8 is formed, that is, a portion except for the circumferential edge in the top surface protrudes in a cylindrical shape. The protruding portion constitutes a placing part 20 on which a semiconductor wafer (hereinafter, referred to as “wafer W”) is disposed as a substrate and stepped part 8 surrounding placing part 20 corresponds to a placing region of a ring member to be described below.

On the top surface of placing part 20, a first electrostatic chuck 21 formed by placing a chuck electrode 22 on an insulating layer is installed and chuck electrode 22 is electrically connected to a DC power supply 23 provided outside processing container 1 through a switch 24. A plurality of discharge outlets (not shown) are formed in first electrostatic chuck 21 such that a heat carrier gas, for example, He gas may be supplied from a gas supply part (not shown) to a minute space between first electrostatic chuck 21 and wafer W.

An elevation pin (not shown) is provided inside supporting table 2 and wafer W may be transferred between a carrying arm (not shown) installed outside the corresponding apparatus and first electrostatic chuck 21.

A refrigerant flowing chamber 35 is installed inside supporting table 2 and is configured such that a refrigerant flows via a path made by a refrigerant supply line 82, refrigerant flowing chamber 35, and a refrigerant discharge line 83. The refrigerant discharged from refrigerant discharge line 83 is cooled to a set temperature by a chiller, and then is returned to refrigerant flowing chamber 35 from refrigerant supply line 82. Therefore, supporting table 2 is maintained at a preset reference temperature by the refrigerant and a temperature of wafer W is determined by heat balance of heat input from plasma and a heat discharge action where heat is discharged to supporting table 2 using He gas.

Supporting table 2 also serves as a lower electrode and is connected with a high-frequency power supply 4 as a bias power supply for applying a bias for injecting ions of plasma to the lower electrode through a matching device 41.

On a ceiling part of processing container 1, a shower head 5 that is a gas supply part for supplying processing gas to a processing region is installed to oppose placing part 20 through an insulating member 12. In shower head 5, a plurality of discharge outlets 51 are formed, and predetermined processing gas from discharge outlets 51 is discharged through a pipe 53 and a buffer chamber 54 from a gas supply system 52 installed outside the processing container. Shower head 5 also serves as an upper electrode and is connected with a high-frequency power supply 56 for generating plasma through a matching device 55.

A wafer W transfer port 14, which is openable and closable by a shutter 13, is provided at the side wall of processing container 1. An exhaust port 15 is installed on the bottom of processing container 1, and is connected with a vacuum pump, which is a vacuum exhaust mechanism, through an exhaust pipe 19 equipped with a valve 17 and a pressure adjusting unit 18.

On a bottom surface (stepped surface) of stepped part 8 formed at the circumferential edge of the top surface of supporting table 2, a ring-shaped second electrostatic chuck 25 formed by disposing a chuck electrode 26 on an insulating layer is installed. At a lateral edge of supporting table 2, a cylindrical quartz member 36 is installed to surround supporting table 2 as an insulating member. A focus ring 3 is installed to span over both of second electrostatic chuck 25 and quartz member 36. An inner circumferential edge of focus ring 3 is notched over the entire circumference to form a stepped part, and a circumferential edge protruding from first electrostatic chuck 21 of wafer W held at first electrostatic chuck 21 fits into the stepped part of focus ring 3.

Second electrostatic chuck 25 is for adsorbing and fixing focus ring 3 and is electrically insulated from first electrostatic chuck 21. Chuck electrode 26 is electrically connected to a DC power supply 27 installed outside processing container 1 through a switch 28 separate from switch 24 of first electrostatic chuck 21. Therefore, first electrostatic chuck 21 and second electrostatic chuck 25 may independently switch ON/OFF of adsorption.

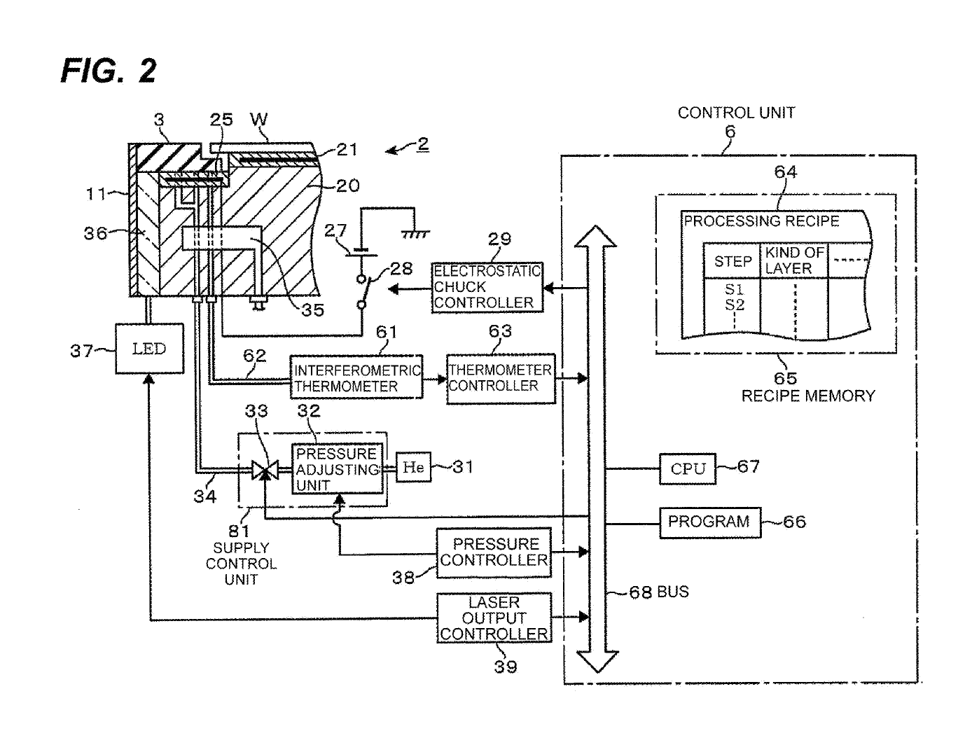

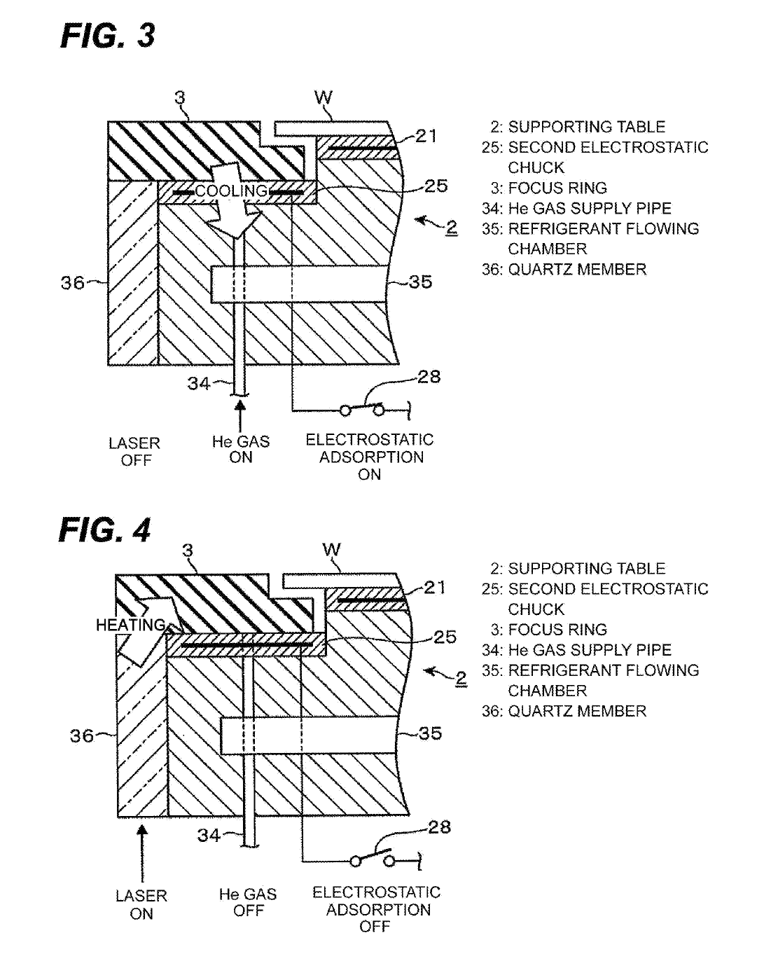

A plurality of discharge outlets (not shown) for supplying a heat carrier gas, for example, He gas, to a minute space between focus ring 3 and second electrostatic chuck 25 are formed in second electrostatic chuck 25. The discharge outlets are connected to a He gas supply source 31 installed outside processing container 1 by a pipe 34 through a supply control unit 81. Since supply control unit 81, as show in FIG. 2, includes a pressure adjusting unit 32, a valve 33, it is possible to supply and interrupt He gas to the discharge outlets and further to adjust supply pressure of the He gas through a pressure controller 38. Therefore, the He gas is supplied to a minute space between focus ring 3 and second electrostatic chuck 25 to discharge heat of focus ring 3 to supporting table 2 through the He gas, as shown in FIG. 3, thereby cooling focus ring 3.

A light source, for example, a light emitting diode (LED) 37 is installed outside processing container 1 and is adapted to emit a laser light for heating focus ring 3. The laser light radiated by LED 37 is dispersed while being transmitted into quartz member 36 so as to be uniformly irradiated to the entire focus ring 3 disposed on quartz member 36. Therefore, as shown in FIG. 4, the laser light is irradiated to focus ring 3 through quartz member 36 by LED 37 thereby heating focus ring 3.

In both cases where focus ring 3 is cooled down as shown in FIG. 3 and focus ring 3 is heated as shown in FIG. 4, the temperature of focus ring 3 is determined based on the balance between the heat input from plasma, the heat discharged to a cooling mechanism and the heat input from a heating mechanism.

A guide ring 11 serving as a cylindrical insulating member for preventing a reaction product from being attached is installed at an outer circumference of focus ring 3 and quartz member 36 to surround focus ring 3 and quartz member 36.

In the plasma etching apparatus, an interferometric thermometer 61 as a temperature detector is installed and a detection terminal thereof is in contact with focus ring 3, as shown in FIG. 2. An optical fiber 62 passing through second electrostatic chuck 25 connects the main body and the detection terminal of thermometer 61. A detected temperature is input to a control unit 6 through a thermometer controller 63.

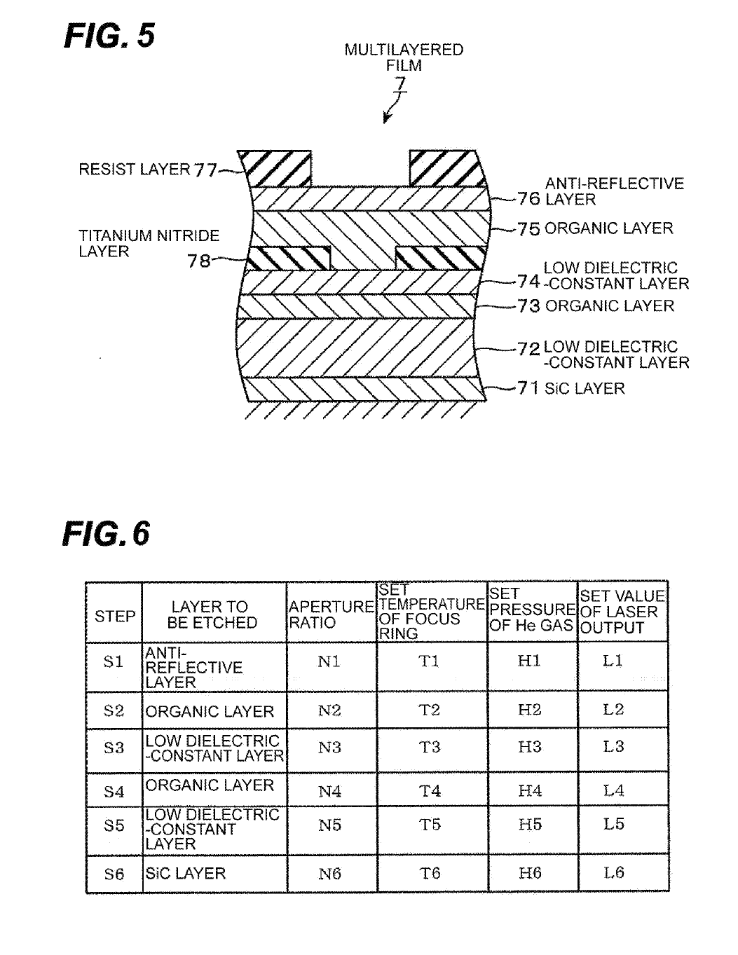

Switches 24, 28 for the electrostatic chucks, valve 33 constituting a part of He gas supply control unit 81, pressure controller 38, and a laser output controller 39 are operated based on a control signal from control unit 6. As shown in FIG. 2, control unit 6 includes a bus 68, a recipe memory 65 storing a processing recipe 64, a CPU 67, and an ROM storing a program (for brevity, ROM is not shown in the figure and a program is denoted by reference numeral 66). Processing recipe 64 refers to data in which an operation order for processing is written together with processing parameters, and program 66 reads out contents of processing recipe 64 to prepare a control signal according to each read-out contents and execute each operation. In this example, CPU 67 and program 66 correspond to an executing part outputting the control signal. In the present exemplary embodiment, wafer W which is to be etched has a multi-layered structure on the surface thereof as shown in FIG. 5 and steps S1 to S3 for sequentially etching layers from top are recorded in processing recipe 64 therefor as shown in FIG. 6. Specifically, in processing recipe 64, a layer to be etched among multilayers, a kind and a flow rate of processing gas, power values to be supplied to upper electrode 5 and lower electrode 2, an aperture ratio of a mask by an etching pattern, a set temperature of focus ring 3, a set pressure of He gas for cooling each of wafer W and focus ring 3, a set value of a laser output in corresponding step S are described for each of steps S1 to S3. In FIG. 6, an example of processing recipe 64 is shown, but only matters associated with the temperature of focus ring 3 are described and the other matters are omitted.

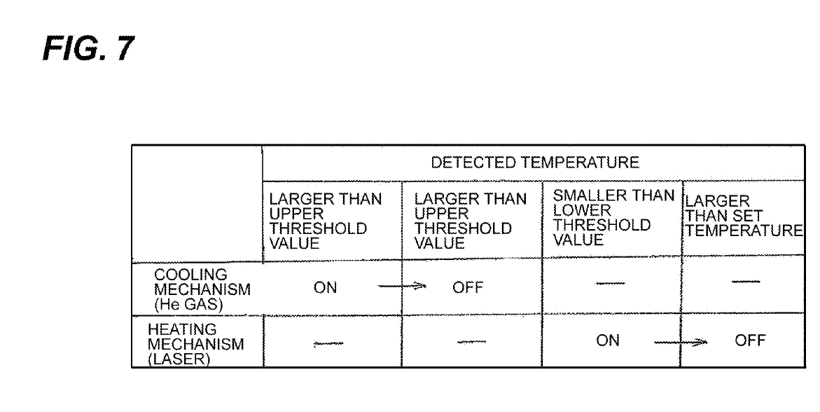

As shown in FIG. 7, a step group of program 66 for setting temperature of focus ring 3 is configured such that when a detected temperature by interferometric thermometer 61 becomes larger than an upper threshold value, the cooling mechanism operates, and thereafter, when the detected temperature becomes smaller than a set temperature, the cooling mechanism stops. On the contrary, when the detected temperature becomes smaller than a lower threshold value, the heating mechanism operates and thereafter, when the detected temperature becomes larger than the set temperature, the heating mechanism stops. The details will be described in the description of an operation of the exemplary embodiment to be described below.

The operation of the present exemplary embodiment will be described. First, wafer W is carried into processing container 1 through a carrying arm (not shown) from a vacuum carrying chamber (not shown) and transferred onto first electrostatic chuck 21 through an elevation pin (not shown) to be adsorbed and maintained. On the surface of wafer W, as shown in FIG. 5, for example, a silicon carbide (SiC) layer 71, a low dielectric-constant layer 72, an organic layer 73, a low dielectric-constant layer 74, an organic layer 75, and an anti-reflective layer 76 are laminated in this order from bottom to form multilayers 7. Reference numerals 77 and 78 denote pattern masks of a resist layer and a titanium nitride layer, respectively.

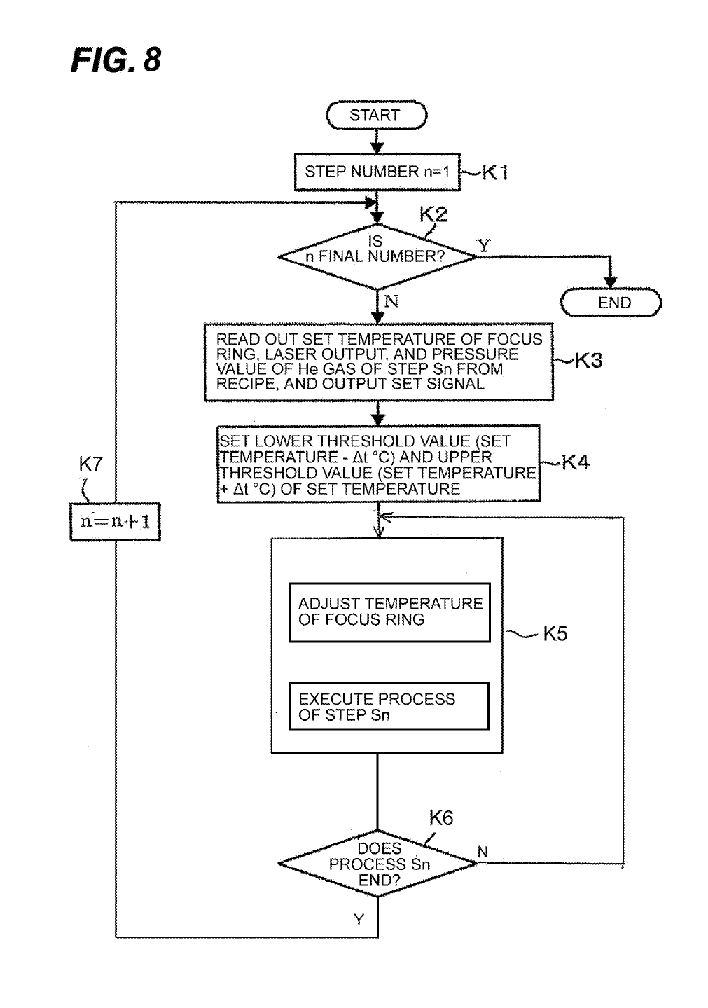

Program 66 reads out the contents of a processing recipe corresponding to wafer W among the processing recipe group stored in recipe memory 65. FIG. 8 represents a step group included in program 66 controlling the temperature of focus ring 3, and an operation will be described with reference to FIGS. 8 to 11 based on the control of the temperature of focus ring 3 in the etching processing. Steps of the flow process of FIG. 8 are represented by “step K” to be distinguished from “step S” included in the processing recipe shown in FIG. 6. First, a number (n) of a step included in the processing recipe is set as “1”. Step K3 is performed after performing step K2, such that a set temperature of focus ring 3, a laser output value, and a pressure value of He gas that are recorded in step S1 are read out, and a set signal is output. Accordingly, laser output controller 39 adjusts power of LED 37 to be a set value and a He gas pressure controller 38 adjusts pressure of He gas to be a set value.

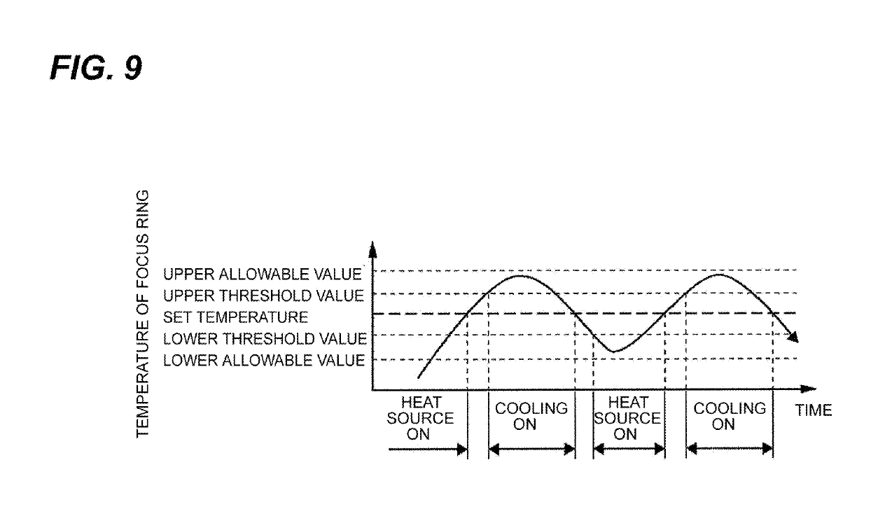

Subsequently, a lower threshold value (set temperature−Δt ° C.) and an upper threshold value (set temperature+Δt ° C.) of a set temperature are set (step K4). While adjusting the temperature of focus ring 3, an etching process of step S1 is performed (steps K5 and K6). Herein, the adjustment of temperature will be described with reference to FIG. 9. A rule for the temperature adjustment of focus ring 3 is determined as follows.

(1) LED 37 is turned ON when a detected temperature of interferometric thermometer 61 is lower than the lower threshold value, and turned OFF when the detected temperature reaches the set temperature.

(2) He gas is turned ON when the detected temperature is higher than the upper threshold value, and turned OFF when the detected temperature reaches the set temperature.

Then, when steps K5 and K6 are repeated and step S1 of processing recipe 64 ends (when a processing time elapses and time is over), the process proceeds from step 6 to step K7, and thus a step number of processing recipe 64 is increased by one. As a result, an etching process of step S2 is performed similarly as in steps K3 to K6.

FIG. 9 is a temperature variation diagram illustrating a set temperature of focus ring 3, a lower threshold value, an upper threshold value, and a temperature variation of focus ring 3 in connection with ON and OFF of LED 37 and He gas. Herein, when the detected temperature is lower than the lower threshold value, as shown in FIG. 9, LED 37 is turned ON, and as a result, the temperature of focus ring 3 rises. At this time, He gas is in an off state (stop state). When the detected temperature reaches the set temperature, LED 37 is turned OFF, but the detected temperature overshoots the set temperature due to a time lag of the heat transfer caused by a distance between a heating location by a laser from LED 37 and a detection location by thermometer 61. When the detected temperature exceeds the upper threshold value due to the overshoot, the He gas is turned ON (He gas starts to be supplied) and thus cooling of focus ring 3 starts. In reality, the time lag occurs until the detected temperature becomes lower than the set temperature due to the time consumed to charge the He gas up to a set pressure, a distance between a charging location of the He gas and a detecting location of thermometer 61. When the detected temperature reaches the set temperature, the supply of the He gas stops. However, in reality, the detected temperature becomes lower than the set temperature, and thus the overshoot occurs due to, for example, the distance between the charging location of the He gas and the detecting location of thermometer 61, He gas remaining after the supply of He gas stops, and heat removal from a point contact location of focus ring 3 and second electrostatic chuck 25. If the detected temperature further lowers and thus falls below the lower threshold value, LED 37 is turned ON and focus ring 3 starts to be heated. Thereafter, the temperature of focus ring 3 is also adjusted and maintained around the set temperature by repeating the aforementioned operation according to the behavior of the detected temperature or the status of the present apparatus. When the detected temperature exceeds an upper allowable value or a lower allowable value, the processing of wafer W stops at that time and corresponding wafer W is considered as a defective wafer.

In the meantime, program 66 also reads out processing parameters in addition to matters associated with focus ring 3 at step S1 of processing recipe 64. Power from high-frequency power supply at an upper electrode 5 side, power from high-frequency power supply (bias power) at a lower electrode 2 side, a kind, a gas flow rate, and pressure of the processing gas are set by the processing parameter, and plasma is generated in a processing atmosphere. As a result, etching of a thin film is performed while ions of plasma are injected into wafer W by the bias power. When the etching time of step S1 is over, the processing parameters of step S2 are read out and a thin film to be subjected to step S2 is etched based on the corresponding processing parameters.

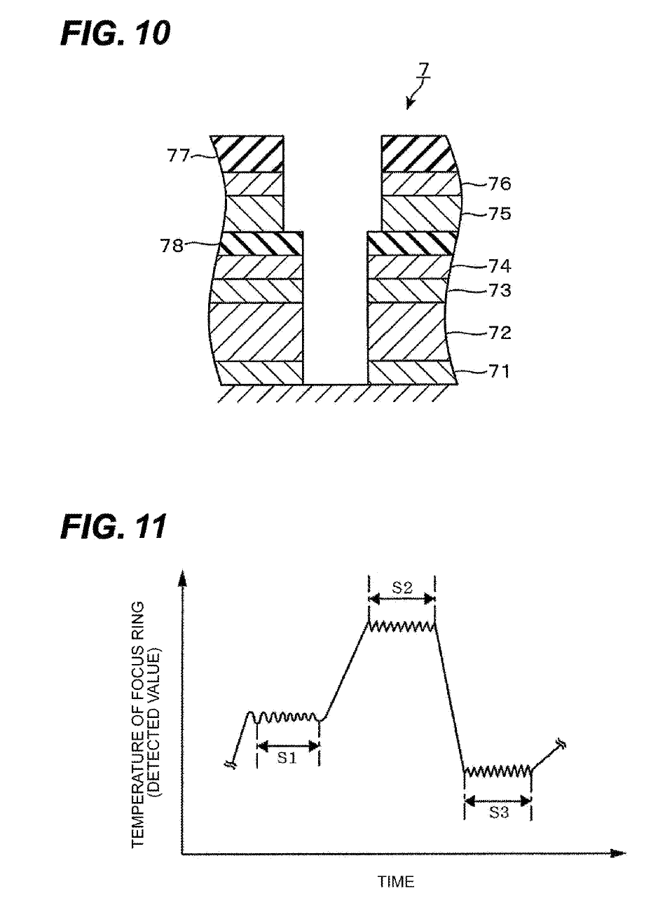

Referring back to FIG. 8, when a step number of processing parameters becomes the final number (in this example, n=6), a series of etching for wafer W ends. FIG. 10 is a longitudinal sectional view schematically illustrating a state at an etching end time of multilayers 7 formed on wafer W. Thereafter, wafer W completed with the processing is carried out from vacuum container 1 by a reverse operation to a carrying-in operation, and a next wafer W is carried in to corresponding vacuum container 1.

FIG. 11 schematically illustrates the relationship between execution timings of steps (S1 to S3 are representatively shown) of processing recipe 64 and the temperature of focus ring 3. In any one of steps S1 to S3, when a set temperature of focus ring 3 is higher in a next step than in the current step, after the current step ends, LED 37 is turned ON to increase the temperature. On the contrary, when the set temperature of focus ring 3 is lower in the next step, He gas is turned ON to lower the temperature after the current step ends. In FIG. 11, in order to facilitate the understanding of a temperature variation, the set temperature does not correspond to a set temperature of a layer to be etched shown in FIG. 6.

According to the aforementioned exemplary embodiment, a proper temperature of focus ring 3 capable of performing an etching process having a high in-plane uniformity is identified in advance for each of multilayers 7 formed on wafer W, the temperature is reflected to processing recipe 64 as a set temperature, and the heating mechanism and the cooling mechanism are controlled such that the temperature of focus ring 3 is within an appropriate temperature range including the set temperature thereof for each of the layers to be successively etched. Therefore, it is possible to perform an etching process with high in-plane uniformity. Since heat radiation is performed using a laser as the heating mechanism of focus ring 3, it is possible to rapidly heat focus ring 3. When cooling focus ring 3, focus ring 3 is configured to discharge heat thereof to supporting table 2 without using a heater as a heat carrier to independently separate the heating mechanism and the cooling mechanism from each other, and thus it is possible to rapidly cool focus ring 3.

In the aforementioned exemplary embodiment, a kind of layer and the set temperature of focus ring 3 correspond to each other. However, since the present inventors figure out that when an aperture ratio (a ratio of an area of an opening of a mask on a layer in respect to the entire area of a device) is different even on the same layer, a proper temperature of focus ring 3 varies, the temperature of focus ring 3 may be set for each combination of the kind of layer and the aperture ratios.

In the aforementioned exemplary embodiment, ON and OFF of second electrostatic chuck 25 is controlled according to ON and OFF of a heating mode and a cooling mode. However, second electrostatic chuck 25 may be maintained to be turned ON at all times including the heating mode.

A scheme of controlling the temperature of focus ring 3 is not limited to the aforementioned ON and OFF control but, for example, a threshold value L1 slightly lower than the set temperature of focus ring 3 and a threshold L2 slightly higher than the set temperature are set in the temperature control scheme, and heating and cooling may be performed as follows. Output power of LED 37 is controlled by a PID amplifier according to a difference between the detected temperature and the set temperature such that when the detected temperature exceeds the set temperature, LED 37 is turned OFF and when the detected temperature becomes equal to or less than threshold L1, output power control of LED 37 is resumed. The pressure of He gas is controlled by a PID amplifier according to a difference between the detected temperature and the set temperature such that when the detected temperature becomes equal to or lower than the set temperature, the He gas is turned OFF and when the detected temperature exceeds threshold value L2, pressure control of the He gas restarts.

As the heating mechanism, other laser light sources generating a laser beam, a heater may be used than the aforementioned LED. The cooling mechanism is not limited to one that utilizes the heat carrier gas such as the He gas as described above, and, for example, may have a configuration in which a cooling laminated body with a Peltier device inserted between adhesive sheets is interposed between focus ring 3 and supporting table 2, and focus ring 3 may be cooled by the Peltier device. In this case, second electrostatic chuck 25 is not used. As the heat carrier gas, gases such as argon (Ar), nitrogen (N₂), methane tetrafluoride (CF₄), and sulphur hexafluoride (SF₆) may be used instead of the He gas. However, the He gas is preferred considering heat conduction coefficients of the gases and the influence on an etching process when these gases are leaked in a plasma space. As the heat carrier, liquid instead of gas, for example, a liquid such as water or an organic solvent (for example, GALDEN) may be used, but the He gas is preferred considering that the configuration of the cooling mechanism of the focus ring becomes complicated and the discharging of the heat carrier liquid is difficult when cooling stops.

The present disclosure includes not only a case where for each wafer W, the number of steps is plural in processing recipe 64 as described above but also a case where only a single layer is etched, that is, the number of aforementioned step is only one. The present disclosure is not limited to etching multilayers 7 of wafer W, but when etching only a single layer of wafer W, the case where a set temperature of focus ring 3 according to the layer is recorded in processing recipe 64 corresponding to wafer W and the temperature of focus ring 3 is controlled according to the set temperature is also included in the present disclosure.

### Example

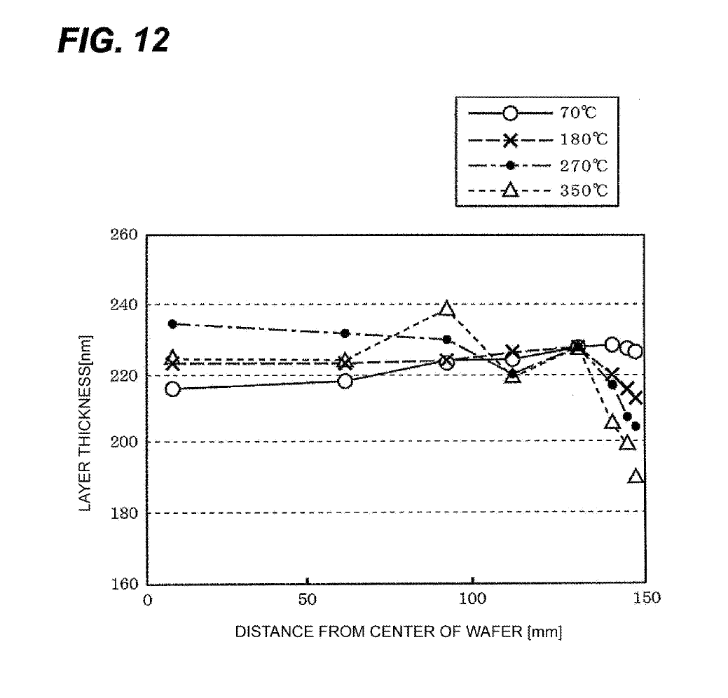

An example in the present disclosure will be described. A trench-shaped pattern was etched on an SiCHO layer that serves as a low-dielectric constant layer formed on a silicon wafer having a diameter of 300 mm using plasma obtained by making process gas including C₄F₈ into plasma. As for the condition, the temperature of the focus ring was changed to 70° C., 180° C., 270° C., and 350° C. while the other processing conditions are not changed. An etching rate on a wafer surface was examined and the results are shown in FIG. 12. When the temperature of the focus ring was 70° C., substantially uniform etching processing results were obtained. However, as the temperature of the focus ring rose, a layer thickness of a circumferential edge of a wafer became smaller as compared to the central portion thereof. From the result, it has been verified that an etching rate of the circumferential edge of the wafer is adjusted by adjusting the temperature of the focus ring, and the in-plane uniformity of the wafer is improved in the etching process by optimizing the temperature of the focus ring.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma etching apparatus for performing an etching process for a substrate using plasma comprising:
a processing container including a placing part configured to place the substrate;
a ring member installed to surround the substrate on the placing part and configured to adjust a plasma state;
a heating mechanism configured to heat the ring member;
a cooling mechanism configured to cool the ring member;
a temperature detector configured to detect a temperature of the ring member;
a storage unit configured to store a processing recipe including a set temperature of the ring member and having processing conditions for etching the substrate recorded therein; and
an executing unit that reads out the processing recipe from the storage unit and outputs a control signal for controlling the heating mechanism and the cooling mechanism based on the set temperature of the ring member and a temperature detected from the temperature detector.

2. The plasma etching apparatus of claim 1, wherein the processing recipe includes a plurality of processing steps and the set temperature of the ring member is set for each step.

3. The plasma etching apparatus of claim 2, wherein plural kinds of layers are laminated on the substrate to be successively etched in the processing container and each of the plurality of processing steps included in the processing recipe corresponds to the respective steps of etching the plural kinds of layers.

4. The plasma etching apparatus of claim 1, wherein the ring member is electrostatically adsorbed onto an electrostatic chuck disposed on the surface of a supporting part that surrounds the placing part and is cooled by a refrigerant, and equipped with a gas supply mechanism configured to supply gas for heat conduction between the ring member and the electrostatic chuck so as to cool the ring member by discharging heat of the ring member to the supporting part side, and the gas supply mechanism constitutes a part of the cooling mechanism and is controlled by the control signal.

5. The plasma etching apparatus of claim 1, wherein the heating mechanism includes an insulator installed at a lower part of the ring member, and a light source unit installed outside the processing container and configured to irradiate light to the ring member through the insulator for heating.

6. A plasma etching method for performing an etching process with plasma onto a substrate disposed on a placing part in a processing container, the method comprising:
reading out a processing recipe corresponding to the substrate to be etched, which includes a set temperature of a ring member and has processing conditions for etching the substrate recorded therein, using the ring member installed to surround the substrate on the placing part and configured to adjust a plasma state, a heating mechanism configured to heat the ring member, and a cooling mechanism configured to cool the ring member;
detecting a temperature of the ring member by a temperature detector; and
controlling the heating mechanism and the cooling mechanism based on the set temperature of the ring member recorded in the read processing recipe and a temperature detected from the temperature detector.

7. The plasma etching method of claim 6, wherein plural kinds of layers are laminated on the substrate to be successively etched in the processing container, the processing recipe includes a plurality of processing steps to etch each of the plural kinds of layers, and the set temperature of the ring member is set for each step.
